(19) United States
(12) Patent Application Publication
(10) Pub. No.: US 2008/0169541 A1
(43) Pub. Date: Jul. 17, 2008

(54) Enhanced durability multimedia card

(76) Inventors: Jeffrey Alan Miks, Chandler, AZ (US); Robert Francis Darveaux, Higley, AZ (US); Chung-Hsing Tzu, Taipei Hsien (TW)

Correspondence Address: STETINA BRUNDA GARRED & BRUCKER, 75 ENTERPRISE, SUITE 250, ALISO VIEJO, CA, 92656, US

(21) Appl. No.: 11/250,816

(22) Filed: Oct. 14, 2005

Related U.S. Application Data
(62) Division of application No. 10/626,814, filed on Jul. 23, 2003, now abandoned.
Application No. 10/626,814 is a continuation-in-part of application No. 09/956,190, filed on Sep. 19, 2001, now Pat. No. 6,900,527.

(51) Int. Cl. H01L 21/00; H01L 23/02

(52) U.S. Cl. 257/679; 438/121; 257/E23.064

(57) ABSTRACT

A memory card comprising a leadframe having a plurality of contacts. Electrically connected to the leadframe is at least one semiconductor die. A body at least partially encapsulates the leadframe and includes opposed top and bottom surfaces, an opposed pair of longitudinal sides, and an opposed pair of lateral sides. The contacts of the leadframe are exposed in the bottom surface of the body and extend to one of the lateral sides thereof.

### CROSS-REFERENCE TO RELATED APPLICATIONS

The present application is a continuation-in-part of U.S. application Ser. No. 09/956,190 entitled LEAD-FRAME METHOD AND ASSEMBLY FOR INTERCONNECTING CIRCUITS WITHIN A CIRCUIT MODULE filed Sep. 19, 2001.

### STATEMENT RE: FEDERALLY SPONSORED RESEARCH/DEVELOPMENT

Not Applicable

### BACKGROUND OF THE INVENTION

The present invention relates generally to memory cards and, more particularly, to a memory card (e.g., a multi-media card (MMC)) which is configured such that the host socket connector pins travel only over the metallic contacts of the memory card and not any mold compound thereof, thus substantially enhancing the durability of the host socket connector pins.

As is well known in the electronics industry, memory cards are being used in increasing numbers to provide memory storage and other electronic functions for devices such as digital cameras, MP3 players, cellular phones, and personal digital assistants. In this regard, memory cards are provided in various formats, including multi-media cards and secure digital cards.

Typically, memory cards comprise multiple integrated circuit devices or semiconductor dies. The dies are interconnected using a circuit board substrate which adds to the weight, thickness, stiffness and complexity of the card. Memory cards also include electrical contacts for providing an external interface to an insertion point or socket. These electrical contacts are typically disposed on the back side of the circuit board substrate, with the electrical connection to the dies being provided by vias which extend through the circuit board substrate.

In an effort to simplify the process steps needed to fabricate the memory card, there has been developed by Applicant a memory card wherein a leadframe assembly is used as an alternative to the circuit board substrate, as described in Applicant's co-pending U.S. application Ser. No. 09/956,190 entitled LEAD-FRAME METHOD AND ASSEMBLY FOR INTERCONNECTING CIRCUITS WITHIN A CIRCUIT MODULE filed Sep. 19, 2001, of which the present application is a continuation-in-part. As is described in Ser. No. 09/956,190, the leadframe and semiconductor die of the memory card are covered with an encapsulant which hardens into a cover or body of the memory card. The body is sized and configured to meet or achieve a “form factor” for the memory card. In the completed memory card, the contacts of the leadframe are exposed within a common surface of the body, with a die pad of the leadframe and the semiconductor die mounted thereto being disposed within or covered by the body.

Applicant has previously determined that the molding or encapsulation process used to form the body of the card sometimes gives rise to structural deficiencies or problems within the resultant memory card. These problems include portions of the die pad of the leadframe being exposed in the body of the memory card, flash being disposed on the contacts of the leadframe, chipping in a peripheral flange area of the body, and mold gate pull-out wherein a portion of the mold or encapsulating compound is pulled out from within the body, leaving a small recess or void therein. To address these particular problems, Applicant has previously developed a memory card having a “die down” configuration attributable to the structural attributes of the leadframe included therein, and an associated molding methodology employed in the fabrication of such memory card. This die-down memory card is disclosed in Applicant's co-pending U.S. application Ser. No. 10/266,329 entitled DIE DOWN MULTI-MEDIA CARD AND METHOD OF MAKING SAME filed Oct. 8, 2002, the disclosure of which is incorporated herein by reference.

Memory cards, such as multi-media cards, are used by advancing the same into a host socket which includes a plurality of connector pins. Many host sockets include nine connector pins to accommodate the seven contacts included in many memory card formats such as multi-media cards, and the nine contacts included in the secure digital card memory card format. In current memory cards, the bottom surfaces of the contacts are exposed in and substantially flush with the bottom surface of the body of the memory card. A relatively narrow rail or segment of the body extends between and thus separates the contacts from the lateral side of the body which is advanced into the host socket. As a result, the connector pins of the host socket must travel over this rail or segment of the mold compound of the body prior to engaging the exposed bottom surfaces of the contacts of the memory card. The travel or rubbing of the connector pins on the mold compound tends to rapidly wear out the connector pins, especially when the mold compound contains-high levels of filler material. As a result, the host socket connector pins are unable to survive the typical mating insertion requirement of ten thousand insertion cycles.

The present invention addresses and overcomes the above-described deficiencies of currently known memory cards by providing a memory card which is specifically configured to eliminate the travel of the host socket connector pins over the mold compound of the body of the memory card. These and other attributes of the present invention will be described in more detail below.

### BRIEF SUMMARY OF THE INVENTION

In accordance with the present invention, there are provided various embodiments of a memory card which is configured in a manner such that the host socket connector pins do not travel over the mold compound of the body of the memory card as a result of an insertion cycle of the memory card into the host socket. More particularly, in accordance with one embodiment of the present invention, the seven contacts or connector pins of a memory card (i.e., a multi-media card) are extended to the adjacent lateral side of the card body so that the host socket connector pins slide or travel only over the contacts of the memory card. In a variation of this configuration, two additional “dummy” contacts are added to the multi-media card to provide protection for the outermost two pins of the nine host socket connector pins that accommodate the nine contacts or pins included in a secure digital card. In an alternative embodiment of the present invention, a laser is used to ablate the mold compound of the body located between the contacts and the adjacent lateral edge or side of the body to create clearance sufficient to prevent the connector pins of the host socket from traveling over or rubbing the card body. In this variation, the above-described dummy pads may also be included to protect the outer two connector pins of the host socket.

The present invention is best understood by reference to the following detailed description when read in conjunction with the accompanying drawings.

### BRIEF DESCRIPTION OF THE DRAWINGS

These, as well as other features of the present invention, will become more apparent upon reference to the drawings wherein:

FIG. 1 is a bottom plan view of a memory card constructed in accordance with a first embodiment of the present invention;

FIG. 2 is a bottom plan view of a memory card constructed in accordance with a second embodiment of the present invention;

FIG. 3 is a bottom plan view of a memory card constructed in accordance with a third embodiment of the present invention;

FIG. 4 is a side-elevational view of the memory card of the third embodiment shown in FIG. 3; and

FIG. 5 is a bottom plan view of a memory card constructed in accordance with a fourth embodiment of the present invention.

Common reference numerals are used throughout the drawings and detailed description to indicate like elements.

### DETAILED DESCRIPTION OF THE INVENTION

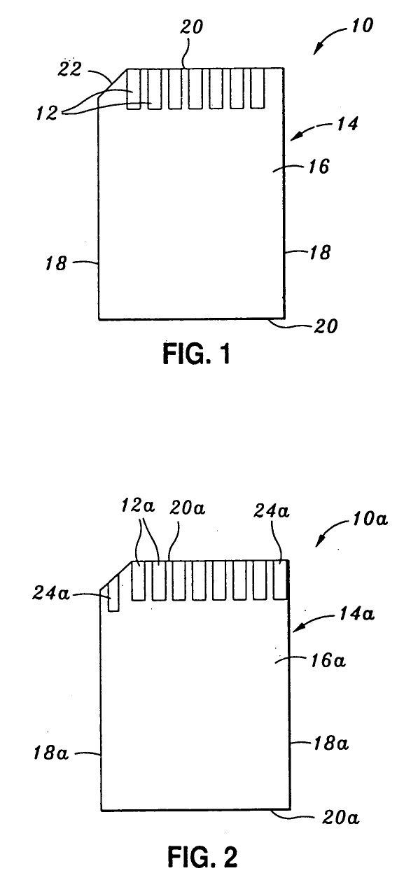

Referring now to the drawings wherein the showings are for purposes of illustrating preferred embodiments of the present invention only, and not for purposes of limiting the same, FIG. 1 depicts a memory card 10 which is constructed in accordance with a first embodiment of the present invention. As shown in FIG. 1, the memory card 10 has a form factor particularly suited for use in a multi-media card memory application. However, those of ordinary skill in the art will recognize that the memory card 10 may have alternative memory card formats, including those of secure digital cards (SDC), compact flash (CF), memory stick, and other small form factor memory cards.

The memory card 10 includes a leadframe having a die attach area or die pad and a plurality of contacts 12. The die pad and contacts 12 each define opposed, generally planar top and bottom surfaces. Integrally connected to and extending from each of the contacts 12 is a conductive trace. The traces terminate in close proximity to the die pad.

In the memory card 10, attached to the die pad is a semiconductor die. Such attachment is preferably facilitated through the use of an epoxy or adhesive. Subsequent to such attachment, the pads or terminals of the semiconductor die are electrically connected to one or more of the traces and/or the die pad through the use of conductive wires or equivalent standard interconnect technology (e.g., flip chip, solder attach, etc.).

The leadframe is preferably fabricated from a conductive metal material (e.g., copper) through either a chemical etching or mechanical stamping process. The leadframe may be formed to include any number of contacts 12 depending on the desired application for the memory card 10. As shown in FIG. 1, the memory card 10 includes seven contacts 12 which is the typical number included for a multi-media card application. The leadframe of the memory card 10 may further be configured to define more than one die pad for accommodating differing numbers of semiconductor dies alone or in combination with other devices such as passive devices. Further, more than one semiconductor die and/or one or more other devices can be attached to a single die pad, or to respective ones of multiple die pads. The pattern of the conductive traces may also be varied depending upon the number and arrangement of die pads and the number of semiconductor dies and/or other passive devices included in the memory card 10. Thus, the configuration of the leadframe of the memory card 10 is variable, in that the number and arrangement of die pads, contacts 12, and conductive traces may be varied as needed to satisfy the requirements of a particular application. Typically, the bottom surfaces of the contacts 12 will be coated with a conductive material.

In fabricating the memory card 10, an encapsulant material or molding compound is applied to the leadframe, the semiconductor die(s), and any conductive wires used to electrically connect the semiconductor die(s) to the die pad and/or traces. The molding compound is preferably a plastic (e.g., thermoset, thermoplastic) which, upon hardening, forms a body 14 of the memory card 10. The completely formed body 14 defines a generally planar top surface, an opposed, generally planar bottom surface 16, an opposed pair of longitudinal edges or sides 18, and an opposed pair of lateral edges or sides 20. The body 14 also defines a fifth sloped or angled side 22 which extends between one of the longitudinal sides 18 and one of the lateral sides 20. The body 14 is formed such that the bottom surfaces of the contacts 12 are exposed in and substantially flush with the bottom surface 16 of the body 14.

As seen in FIG. 1, the contacts 12 each extend to that lateral side 20 of the body 14 which is adjacent the sloped side 22. The extension of the contacts 12 to such lateral side 20 represents a substantial departure from existing memory cards wherein a continuous, relatively narrow rail or segment of the body extends between the contacts and the lateral side of the body disposed closest thereto. As indicated above, the travel or rubbing of the connector pins of the host socket over such rail or segment of the body substantially accelerates the wear of the connector pins, thus resulting in the inability of existing memory cards to meet or exceed the typical requirement of ten thousand insertion cycles without failure.

To achieve the above-described orientations between the contacts 12 and body 14 in the memory card 10, it is contemplated that the body 14 will be molded in a manner achieving a desired form factor which, in the case of the memory card 10, is a multi-media card form factor as indicated above. The molding techniques which may be employed to facilitate the formation of the body 14 with a prescribed form factor are described with particularity in U.S. application Ser. No. 10/266,329 which, as indicated above, is incorporated herein by reference. In this regard, the memory card fabrication methodology wherein a “skin” is mated to a circuit module as also described in U.S. application Ser. No. 10/266,329 is not well suited for the memory card 10 since such skin would typically define the undesirable rail or segment of material between the contacts and that lateral side of the memory card which is disposed closest to the contacts, such lateral side being defined by the skin itself. Additionally, in the memory card 10, the leadframe defining the contacts 12 may be configured to accommodate attachment of the semiconductor die(s) to the top surface of the die pad as described in U.S. application Ser. No. 09/956,190 or to the bottom surface of the die pad in a “die down” configuration as described in U.S. application Ser. No. 10/266,329.

Referring now to FIG. 2, there is shown a memory card 10a constructed in accordance with a second embodiment of the present invention. The memory card 10a is identical to the memory card 10 of the first embodiment in all respects, except that the leadframe of the memory card 10a further includes two dummy pads 24a which each define a bottom surface exposed in and substantially flush with the bottom surface 16a of the body 14a of the memory card 10a. One of these dummy pads 24a extends to the sloped side 22a of the body 14a of the memory card 10a. and thus is disposed between the longitudinal side 18a of the body 14a which extends to the sloped side 22a and one of the contacts 12a of the memory card 10a. The remaining dummy pad 24a, like the contacts 12a, extends to that lateral side 20a of the body 14a which extends to the sloped side 22a. Such remaining dummy pad 24a is disposed between one of the contacts 12a and that longitudinal side 18a of the body 14a which does not extend to the sloped side 22a.

As indicated above, the memory card 10 includes seven contacts 12, thus being adapted for use in a multi-media card application. The host socket in which the memory card 10 is advanced will typically include nine connector pins to accommodate not only the memory card 10, but further to accommodate those memory cards which are configured as secure digital cards and include nine contacts. In this regard, though the memory card 10a includes seven contacts 12a in a multi-media card format, the inclusion of the additional dummy pads 24a causes the memory card 10a to mimic a secure digital card format, the dummy pads 24a thus effectively protecting the outermost two connector pins of the host socket from wear. In this regard, rather than such outer two connector pins of the host socket traveling or rubbing across the body 14a, they travel only across the metal material of the dummy pads 24a.

Though, as indicated above, the memory cards 10, 10a each have a form factor of a multi-media card, those of ordinary skill in the art will recognize that the principles of the present invention may be applied to memory cards having alternative formats, such as a secure digital card format. For example, in applying the principles of the present invention to a memory card in a secure digital card format, the nine contacts of such secure digital card would extend to the lateral side or edge of the card disposed closest thereto.

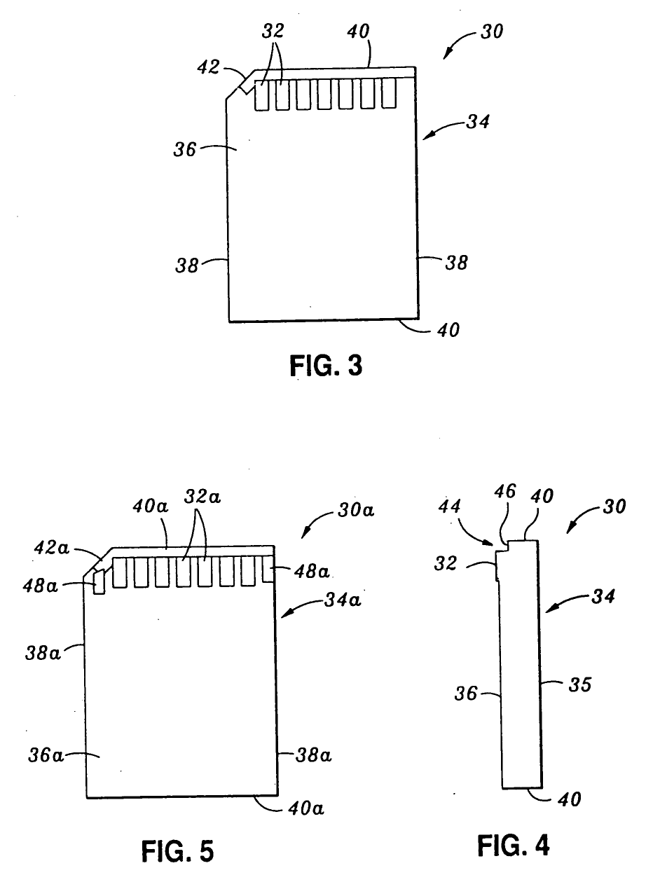

Referring now to FIGS. 3 and 4, there is shown a memory card 30 constructed in accordance with a third embodiment of the present invention. The memory card 30 includes a leadframe having a die attach area or die pad and a plurality of contacts 32. The die pad and contacts 32 each define opposed, generally planar top and bottom surfaces. Integrally connected to and extending from each of the contacts 32 is a conductive trace. The traces terminate in close proximity to the die pad. Attached to the die pad is a semiconductor die. Such attachment is preferably facilitated through the use of an epoxy or adhesive. Subsequent to such attachment, the pads or terminals of the semiconductor die are electrically connected to one or more of the traces and/or the die pads through the use of conductive wires or equivalent standard interconnect technology (e.g., flip chip, solder attach, etc.). The material used to fabricate the leadframe and the possible variations in the structural attributes thereof and arrangement of components attached thereto is the same as discussed above in relation to the memory card 10.

In fabricating the memory card 30, an encapsulant material or molding compound is applied to the leadframe, the semiconductor die(s), and any conductive wires used to electrically connect the semiconductor die(s) to the die pad and/or traces. The molding compound is preferably a plastic (e.g., thermoset, thermoplastic) which, upon hardening, forms a body 34 of the memory card 30. The completely formed body 34 defines a generally planar top surface 35, an opposed, generally planar bottom surface 36, an opposed pair of longitudinal edges or sides 38, and an opposed pair of lateral edges or sides 40. The body 34 also defines a fifth, sloped or angled side 42 which extends between one of the longitudinal sides 38 and one of the lateral sides 40. The body 34 is formed such that the bottom surfaces of the contacts 32 are exposed in and substantially flush with the bottom surface 36 of the body 34.

In the memory card 30, the body 34 is formed in accordance with current techniques such that a continuous, relatively narrow rail or segment of the body 34 initially extends between and thus separates the contacts 32 from the lateral side 40 of the body 34 disposed closest thereto. To eliminate occurrences of the travel or rubbing of the connector pins of the host socket over such rail or segment of the body 34, in the memory card 30, the body 34 is subjected to a laser ablation process which effectively removes or ablates a portion of the rail of the body 34 which extends between the contacts 32 and adjacent lateral side 40. As seen in FIGS. 3 and 4, the laser ablation process results in the formation of a clearance notch 44 in the body 34. The notch 44 is partially defined by a shoulder 46 which is perpendicularly recessed or offset relative to the bottom surface 36 of the body 34. As is seen in FIG. 3, the notch 44 extends along the entirety of the lateral side 40 disposed closest to the contacts 32, and also along a portion of the sloped side 42 of the body 34. As will be recognized, the notch 44 provides a level of clearance sufficient to prevent the connector pins of the host socket from rubbing or traveling across the body 34 upon the insertion of the memory card 30 into the host socket.

The body 34 of the memory card 30 may be molded in a manner achieving a desired form factor which, in the case of the memory card 30, is a multi-media card form factor as indicated above. The molding techniques which may be employed to facilitate the formation of the body 34 with a prescribed form factor are described with particularity in U.S. application Ser. No. 10/266,329. Additionally, the memory card fabrication methodology wherein a “skin” is mated to a circuit module as also described in U.S. application Ser. No. 10/266,329 may also be used in relation to the memory card 30 since a portion of such skin may be ablated in the above-described manner as needed to prevent the connector pins of the host socket from traveling thereover. In the memory card 30, the leadframe defining the contacts 32 may be configured to accommodate the attachment of the semiconductor die(s) to the top surface of the die pad as described in U.S. application Ser. No. 09/956,190 or to the bottom surface of the die pad in a “die down” configuration as described in U.S. application Ser. No. 10/266,329.

Referring now to FIG. 5, there is shown a memory card 30a constructed in accordance with a fourth embodiment of the present invention. The memory card 30a is identical to the memory card 30 of the third embodiment in all respects, except that the leadframe of the memory card 30a further includes two dummy pads 48a which each define a bottom surface exposed in and substantially flush with the bottom surface 36a of the body 34a of the memory card 30a. One of these dummy pads 48a extends to the sloped side 42a of the body 34a of the memory card 30a, and thus is disposed between the longitudinal side 38a of the body 34a which extends to the sloped side 42a and one of the contacts 32a of the memory card 30a. The remaining dummy pad 48a, like the contacts 32a, extends to the lateral side 40a of the body 34a which extends to the sloped side 42a. Such remaining dummy pad 48a is disposed between one of the contacts 32a and that longitudinal side 38a of the body 34a which does not extend to the sloped side 42a. The dummy pads 48a of the memory card 30a provide the same functionality as described above in relation to the dummy pads 24a of the memory card 10a.

This disclosure provides exemplary embodiments of the present invention. The scope of the present invention is not limited by these exemplary embodiments. Numerous variations, whether explicitly provided for by the specification or implied by the specification, such as variations in structure, dimension, type of material and manufacturing process may be implemented by one of skill in the art in view of this disclosure.

1-8. (canceled)

9. A memory card comprising:
a leadframe having a plurality of contacts;
at least one semiconductor die electrically connected to the leadframe; and
a body at least partially encapsulating the leadframe and including:
opposed top and bottom surfaces;
an opposed pair of longitudinal sides; and
an opposed pair of lateral sides;
the contacts of the leadframe being exposed in the bottom surface of the body and extending to a notch formed in the body and extending along one of the lateral sides thereof.

10. The memory card of claim 9 wherein:
the bottom surface of the body is generally planar; and
each of the contacts defines a generally planar bottom surface which is substantially flush with the bottom surface of the body.

11. The memory card of claim 9 wherein the body further includes a sloped side which extends between one of the lateral sides and one of the longitudinal sides thereof, the notch extending along the lateral side which extends to the sloped side and along at least a portion of the sloped side.

12. The memory card of claim 9 wherein the leadframe includes seven contacts.

13. The memory card of claim 9 wherein the leadframe further includes a pair of dummy pads which are exposed in the bottom surface of the body and extend to the notch.

14. The memory card of claim 13 wherein the leadframe includes seven contacts.

15. The leadframe of claim 13 wherein:
the body further includes a sloped side which extends between one of the longitudinal sides and one of the lateral sides thereof, the notch extending along at least a portion of the sloped side and along the lateral side which extends to the sloped side; and
one of the dummy pads extends to a portion of the notch extending along the sloped side, with the remaining one of the dummy pads extending to a portion of the notch which extends along one of the lateral sides.

16. The memory card of claim 9 wherein the notch is partially defined by a shoulder which is perpendicularly recessed relative to the bottom surface of the body.

17. A method of fabricating a memory card, comprising the steps of:
a) providing a leadframe having a plurality of contacts;
b) electrically connecting at least one semiconductor die to the leadframe;
c) partially encapsulating the leadframe and the semiconductor die with a body which includes opposed top and bottom surfaces, an opposed pair of longitudinal sides, and an opposed pair of lateral sides; and
d) ablating a portion of the body in a manner facilitating the formation of a notch which extends between the contacts and one of the lateral sides of the body.

18. The method of claim 17 wherein step (d) is accomplished through the use of a laser.

19. The method of claim 17 wherein:
step (c) comprises forming the body to include a sloped side which extends between one of the lateral sides and one of the longitudinal sides thereof; and
step (d) comprises ablating the body such that the notch extends along at least a portion of the sloped side and along the lateral side which extends to the sloped side.

20. The method of claim 19 wherein:
step (a) comprises providing a leadframe which further includes a pair of dummy pads;
step (c) comprises forming the body such that the dummy pads are exposed in the bottom surface thereof; and
step (d) comprises ablating the body such that each of the dummy pads and each of the contacts extends to the notch formed in the body.

21. A memory card for insertion into a host socket having connector pins, the memory card comprising:
a leadframe having a plurality of contacts;
at least one semiconductor die electrically connected to the leadframe; and
a body at least partially encapsulating the leadframe and including:
opposed top and bottom surfaces;
a first pair of opposed sides; and
a second pair of opposed sides, one of the opposed sides of the second pair defining a leading edge of the body;
the contacts of the leadframe being exposed in the bottom surface of the body and disposed in spaced relation to the leading edge thereof, the body being formed such that the connector pins of the host socket do not travel over the body prior to engaging the contacts when the memory card is advanced into the host socket.

22. The memory card of claim 21 wherein:
the bottom surface of the body is generally planar; and
each of the contacts defines a generally planar bottom surface which is substantially flush with the bottom surface of the body.

23. The memory card of claim 21 wherein the body further includes a sloped side which extends between one of the sides of the first pair and one of the sides of the second pair.

24. The memory card of claim 21 wherein the leadframe includes seven contacts.

25. The memory card of claim 21 wherein:
the leadframe further includes a pair of dummy pads which are exposed in the bottom surface of the body and disposed in spaced relation to the leading edge thereof; and
the body is formed such that the connector pins of the host socket do not travel over the body prior to engaging the dummy pads when the memory card is advanced into the host socket.

26. The memory card of claim 25 wherein the leadframe includes seven contacts.

27. The memory card of claim 25 wherein the body further includes a sloped side which extends between one of the sides of the first pair and one of the sides of the second pair.

28. The memory card of claim 21 wherein the contacts extend to a notch which is formed in the body.
